(19) United States
(12) Patent Application Publication
(10) Pub. No.: US 2026/0040612 A1
(43) Pub. Date: Feb. 5, 2026

(54) SEMICONDUCTOR DEVICE AND METHOD OF MANUFACTURING THE SAME

(71) Applicant: Renesas Electronics Corporation, Tokyo (JP)

(72) Inventor: Takahiro MARUYAMA, Tokyo (JP)

(21) Appl. No.: 19/253,454

(22) Filed: Jun. 27, 2025

(30) Foreign Application Priority Data
Aug. 5, 2024 (JP) 2024-128895

(51) Int. Cl. H10D 30/66; H01L 21/321; H10D 30/01; H10D 64/00; H10D 64/66

(52) U.S. Cl. CPC H10D 30/665; H01L 21/3212; H10D 30/0297; H10D 30/668; H10D 64/112; H10D 64/117; H10D 64/661

(57) ABSTRACT

A field plate electrode configured from a first conductive film is formed in a trench. The field plate electrode is recessed. A first insulation film in the trench is recessed. A gate insulation film is formed in the trench and, simultaneously, a second insulation film is formed so as to cover the field plate electrode. A gate electrode configured from a second conductive film is formed in the trench. A portion of the gate electrode covering a drawer portion, which is a part of the field plate electrode via the second insulation film, is selectively removed.

### CROSS-REFERENCE TO RELATED APPLICATIONS

The present application claims priority from Japanese Patent Application No. 2024-128895 filed on Aug. 5, 2024, the content of which is hereby incorporated by reference to this application.

### BACKGROUND

The present invention relates to a semiconductor device and a method of manufacturing the same, particularly, to a semiconductor device having a gate electrode and a field plate electrode in a trench and a method of manufacturing the semiconductor device.

In a semiconductor device having a semiconductor element like a power Metal Oxide Semiconductor Field Effect Transistor (MOSFET), a trench gate structure in which a gate electrode is embedded in an inside of a trench is applied. As one type of the trench gate structure, there is a split gate structure in which the field plate electrode is formed on a lower portion of the trench and the gate electrode is formed on an upper portion of the trench. To the field plate electrode, a source potential is supplied from the source electrode. A depletion layer is expanded in a drift region by this field plate electrode, thereby being capable of making the drift region highly concentrated and making the drift region lower resistance.

There is a disclosed technique listed below.
[Patent Document 1] Japanese Unexamined Patent Application Publication No. 2011-199109

For example, Patent Document 1 discloses a MOSFET having a split gate structure. A field plate electrode and a gate electrode of Patent Document 1 are formed as follows. Firstly, after the field plate electrode is formed in the trench, an upper surface of the field plate electrode is recessed. Next, a conductive film for the gate electrode is deposited on a semiconductor substrate so as to fill the trench on the field plate electrode. Then, by performing an anisotropic etching processing, the gate electrode is formed on an upper portion of the trench.

### SUMMARY

FIG. 20 shows a semiconductor device of a first consideration example considered by the inventor of the present application based on Patent Document 1 and the like. A part of a field plate electrode FP configures a drawer portion FPa in order to be electrically connected to a source electrode. The field plate electrode FP of the drawer portion FPa is formed not only at a lower portion of the trench TR but also at the upper portion of the trench.

The field plate electrode FP is formed in the trench TR via a thick insulation film IF1. Next, by removing one portion of the field plate electrode, this field plate electrode FP is recessed toward the lower portion of the trench TR from the upper portion of the trench TR, but the other portion of the field plate electrode FP is left as a drawer portion FPa. Next, by removing one portion of the insulation film IF1, this insulation film IF1 is recessed toward the lower portion of the trench TR from the upper portion of the trench TR. Next, a trench insulation film GI is formed in the trench TR on the insulation film IF1, and an insulation film IF2 is formed so as to cover the field plate electrode FP exposed from the insulation film IF1. Next, a conductive film CF2 for the gate electrode is deposited.

Next, by performing the anisotropic etching processing to the conductive film CF1, the gate electrode is formed above the trench TR. At this time, a residue RS1 of the conductive film CF2 may be left on a side surface of the drawer portion FPa. At the time of an operation of the MOSFET, for example, a source potential Vs of 0 V is supplied to the drawer portion FPa and, for example, a drain potential Vd of 100 V is supplied to a drift region NV (semiconductor substrate SUB).

Usually, a dielectric voltage between the drawer portion FPa and the drift region NV is maintained by a thickness of the insulation film IF1. However, if the residue RS1 in an electrical floating state exists, capacity between the drawer portion FPa and the residue RS1 and capacity between the residue RS1 and the drift region NV configure series capacity. Since a volt of 100 V is applied to this series capacity, there is a problem in which the dielectric voltage between the drawer portion FPa and the drift region NV cannot be maintained. That is, reliability of the semiconductor device decreases.

Particularly, if the thickness of the insulation film IF1 is increased to improve the dielectric voltage, a time of an isotropic etching processing for recessing the insulation film IF1 needs to be lengthened, so that the residue RS1 is easily formed up to a deeper position. In addition, since a space between the gate insulation film G1 and the insulation film IF2 also spreads, the larger residue RS1 is easily formed.

Accordingly, by suppressing occurrence of such a residue RS1, a technique for improving the reliability of the semiconductor device is demanded. In addition, it is desirable to be able to suppress an increase in manufacturing costs. Other problems and novel features will be apparent from the present specification and the accompanying drawings.

A typical embodiment in embodiments disclosed in the present application will be briefly explained as follows.

A method of manufacturing a semiconductor device according to one embodiment includes: (a) preparing a semiconductor substrate of a first conductive type, the semiconductor substrate having an upper surface and a lower surface; (b) forming a trench in the semiconductor substrate; (c) forming a first insulation film on the upper surface of the semiconductor substrate and at an inside of the trench; (d) forming a first conductive film on the first insulation film so as to fill the trench; (e) removing the first conductive film located outside the trench, thereby forming as a field plate electrode the first conductive film left in the trench; (f) recessing the field plate electrode; (g) removing the first insulation film located on the upper surface of the semiconductor substrate and, simultaneously, recessing the first insulation film lying in the trench; (h) a gate in the trench, forming insulation film and, simultaneously, forming a second insulation film so as to cover the field plate electrode; (i) forming a second conductive film on the gate insulation film and the second insulation film; (j) removing the second conductive film located outside the trench, thereby forming as a gate electrode the second conductive film left in the trench; and (k) selectively removing a portion covering a drawer portion, which is a part of the field plate electrode via the second insulation film, in the gate electrode.

A semiconductor device according to one embodiment includes: a semiconductor substrate of a first conductive type; a trench forming in the semiconductor substrate; a field plate electrode formed in the trench; and a gate electrode formed above the field plate electrode in the trench. A part of the field plate electrode configures a drawer portion for supplying a potential to the field plate electrode, and an upper surface of the field plate electrode including the drawer portion is lower than the upper surface of the semiconductor substrate.

According to one embodiment, the reliability of the semiconductor device can be improved, and the manufacturing costs can be reduced.

### BRIEF DESCRIPTION OF THE DRAWINGS

FIG. 1 is a plan view showing a semiconductor device according a first embodiment.

FIG. 2 is a plan view showing a main part of the semiconductor device according to the first embodiment.

FIG. 3 is a plan view showing a main part of the semiconductor device according to the first embodiment.

FIG. 4 is a cross-sectional view showing the semiconductor device according to the first embodiment.

FIG. 5 is a cross-sectional view showing the semiconductor device according to the first embodiment during its manufacturing process.

FIG. 6 is a cross-sectional view showing the manufacturing process subsequential to FIG. 5.

FIG. 7 is a cross-sectional view showing the manufacturing process subsequential to FIG. 6.

FIG. 8 is a cross-sectional view showing the manufacturing process subsequential to FIG. 7.

FIG. 9 is a cross-sectional view showing the manufacturing process subsequential to FIG. 8.

FIG. 10 is a cross-sectional view showing the manufacturing process subsequential to FIG. 9.

FIG. 11 is a cross-sectional view showing the manufacturing process subsequential to FIG. 10.

FIG. 12 is a cross-sectional view showing the manufacturing process subsequential to FIG. 11.

FIG. 13 is a cross-sectional view showing the manufacturing process subsequential to FIG. 12.

FIG. 14 is a cross-sectional view showing the manufacturing process subsequential to FIG. 13.

FIG. 15 is a cross-sectional view showing the manufacturing process subsequential to FIG. 14.

FIG. 16 is a cross-sectional view showing the manufacturing process subsequential to FIG. 15.

FIG. 17 is a cross-sectional view showing the manufacturing process subsequential to FIG. 16.

FIG. 18 is a cross-sectional view showing the manufacturing process subsequential to FIG. 17.

FIG. 19 is a flowchart comparing each manufacturing process of the first embodiment with each manufacturing process of a second consideration example.

FIG. 20 is a cross-sectional view showing a semiconductor device of a first consideration example.

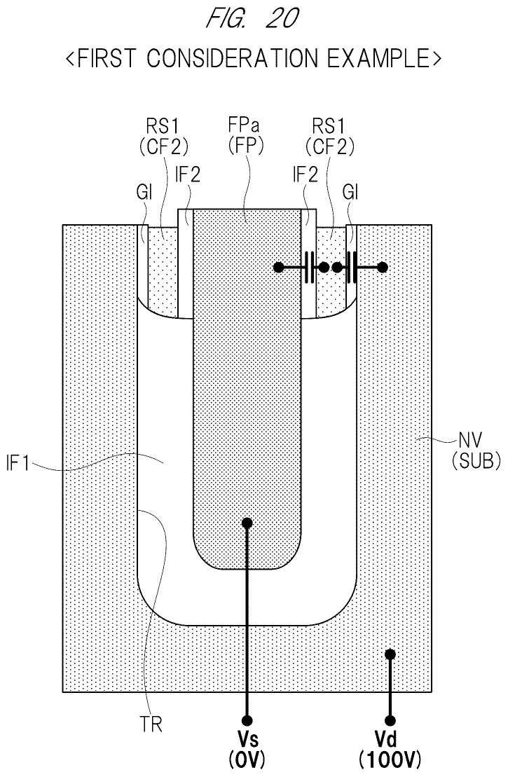

FIG. 21 is a cross-sectional view showing the semiconductor device of the second consideration example during its manufacturing process.

FIG. 22 is a cross-sectional view showing the manufacturing process subsequential to FIG. 21.

FIG. 23 is a cross-sectional view showing the manufacturing process subsequential to FIG. 22.

FIG. 24 is a cross-sectional view showing the manufacturing process subsequential to FIG. 23.

FIG. 25 is a cross-sectional view showing the manufacturing process subsequential to FIG. 24.

FIG. 26 is a cross-sectional view showing the manufacturing process subsequential to FIG. 25.

FIG. 27 is a cross-sectional view showing the manufacturing process subsequential to FIG. 26.

FIG. 28 is a cross-sectional view showing the manufacturing process subsequential to FIG. 27.

FIG. 29 is cross-sectional view showing a reason why a polishing processing is necessary in the second consideration example.

FIG. 30 is a cross-sectional view showing the manufacturing process subsequential to FIG. 28.

FIG. 31 is a cross-sectional view showing the manufacturing process subsequential to FIG. 30.

### DETAILED DESCRIPTION

Hereinafter, embodiments of the present invention will be described in detail with reference to the accompanying drawings. Note that components having the same function are denoted by the same reference characters throughout the drawings for describing the embodiments, and the repetitive description thereof will be omitted. In addition, the description of the same or similar portions is not repeated in principle unless particularly required in the following embodiments.

In addition, an X direction, a Y direction, and a Z direction that are explained in the present application intersected with one another and are orthogonal to one another. In the present application, the Z direction will be explained as a vertical direction, a height direction, or a thickness direction of a certain structure body. Further, an expression such as “a planar view” or “a plan view” used in the present application means, as a plan, a surface formed by the X direction and the Y direction and means to view this “plane” from the Z direction.

### First Embodiment

### Structure of Semiconductor Device

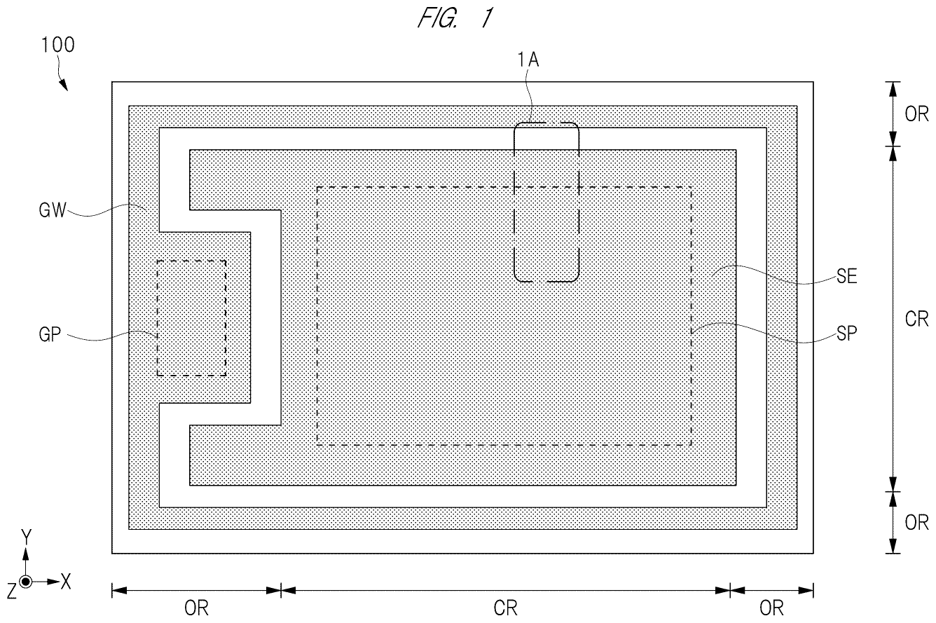

Hereinafter, by using FIG. 1 to FIG. 4, a semiconductor device 100 according to a first embodiment will be explained. The semiconductor device 100 includes a trench-structure MOSFET as a semiconductor element. The MOSFET of the first embodiment has a split gate structure including a gate electrode GE and a field plate electrode FP.

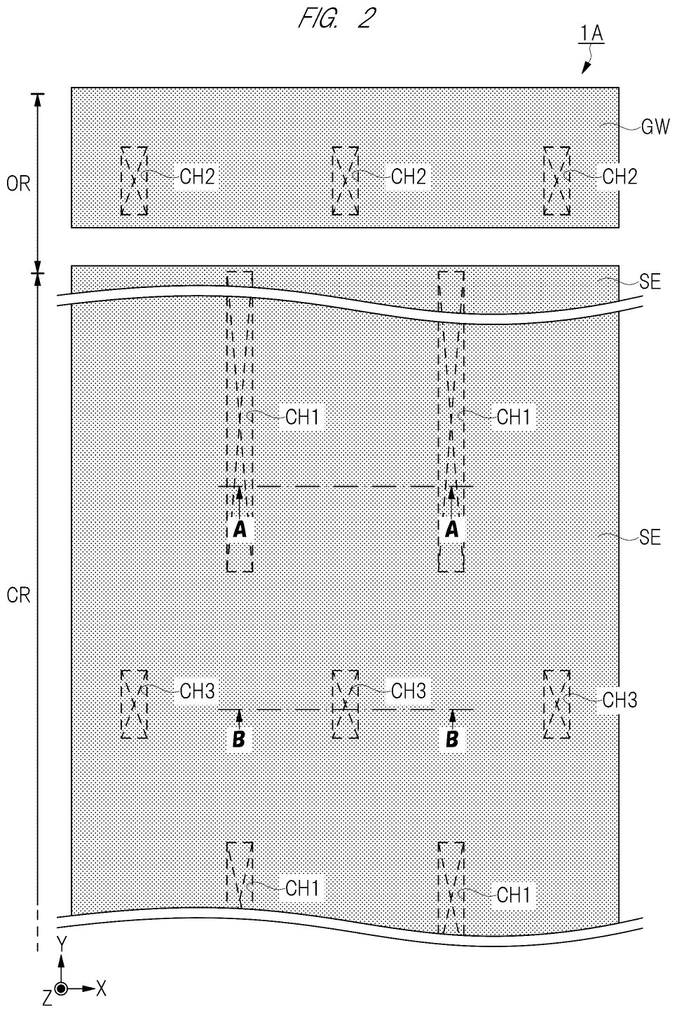

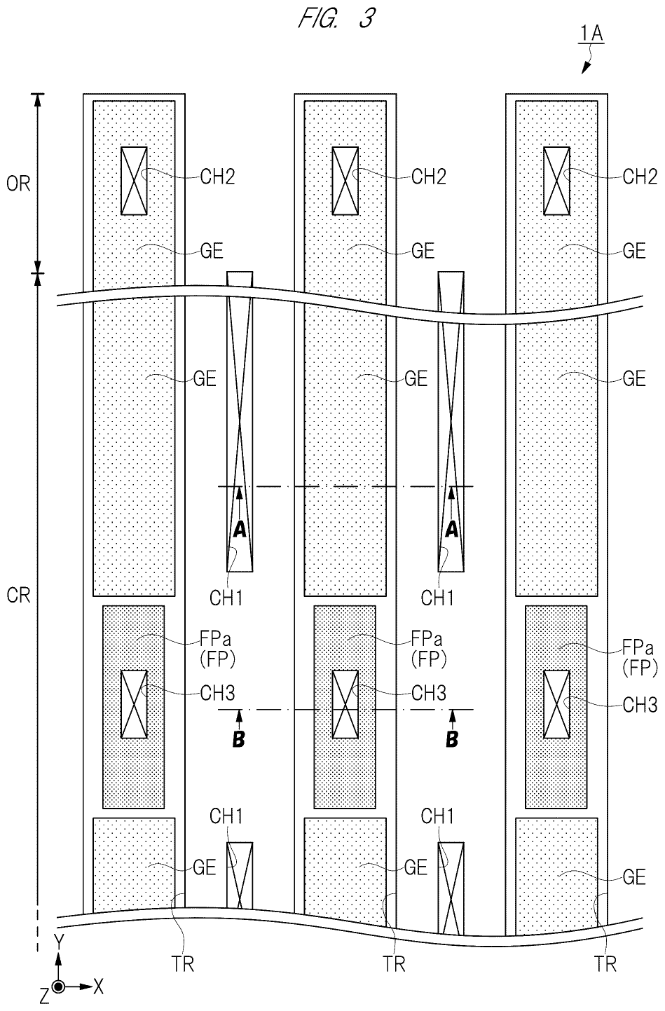

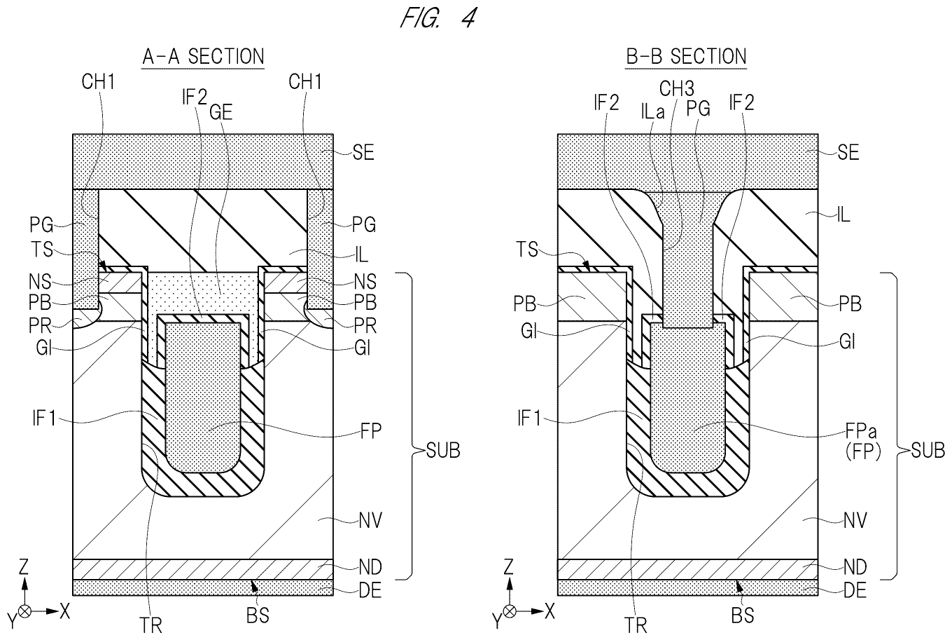

FIG. 1 is a plan view of a semiconductor chip that the semiconductor device 100 is. FIG. 2 is a plan view of a main part expanding a region 1A shown by FIG. 1. FIG. 3 shows a structure body below FIG. 2, and mainly shows a trench gate structure formed in a semiconductor substrate SUB. In addition, positions of a hole CH1, a hole CH2, and a hole CH3 that are shown by FIG. 2 match with a hole CH1, a hole CH2, and a hole CH3 shown by FIG. 3. FIG. 4 is cross-sectional views taken along A-A line and B-B line shown by FIG. 2 and FIG. 3.

FIG. 1 mainly shows a wiring pattern formed above the semiconductor substrate SUB. The semiconductor device 100 has a cell region CR, and an outer circumferential region OR surrounding the cell region CR in a plan view. In the cell region CR, the main semiconductor element like a plurality of MOSFTs is formed. The outer circumferential region OR is used for connection of a gate wiring GW to the gate electrode GE, for a function as a termination region, and for the like.

As shown in FIG. 1 and FIG. 2, a most portion of the cell region CR is covered with a source electrode SE. In the plan view, the gate wiring GW surrounds the source electrode SE. In addition, although not illustrated here, the source electrode SE and the gate wiring GW are covered with a protection film like a polyimide film. A part of the protection film is provided with an opening, and the source electrode SE and the gate wiring GW exposed from the opening become a source pad SP and a gate pad GP. By external connection members being connected on the source pad SP and the gate pad GP, the semiconductor device 100 is electrically connected to another semiconductor chip, a lead frame, a wiring board, or the like. Note that the external connection member is a wire made of, for example, aluminum, gold, or copper, a clip made of a copper plate, or the like.

As shown in FIG. 3, on the semiconductor substrate SUB of a cell region CR, a plurality of trenches TR are formed. The plurality of trenches TR are formed into stripe shapes, extend an X direction, and are separated from each other in the X direction.

As shown by an A-A section of FIG. 4, in the trench TR, the field plate electrode FP is formed at the lower portion of the trench TR, and the gate electrode GE is formed at the upper portion of the trench TR. The field plate electrode GE and the gate electrode GE extend in a Y direction along the trench CH.

As shown by a B-B section of FIG. 4, a part of the field plate electrode FP configures a drawer portion FPa. The drawer portion FPa is located, in the field plate electrode FP, at a position provided for supplying a source potential to the field plate electrode FP.

As shown in FIG. 3, in the cell region CR, the hole CH3 is formed on the drawer portion FPa. The drawer portion FPa is electrically connected to the source electrode SE via the hole CH3. In addition, in the cell region CR, the hole CH1 is formed on a body region PB and a source region NS that are described below. The body region PB and the source region NS are electrically connected to the source electrode SE via the hole CH1. In the outer circumferential region OR, the hole CH2 is formed on the gate electrode GE. The gate electrode GE is electrically connected to the gate wiring GW via the hole CH2.

Hereinafter, by using FIG. 4, a sectional structure of the semiconductor device 100 will be explained.

As shown in FIG. 4, the semiconductor device 100 has the n-type semiconductor substrate SUB having an upper surface TS and a lower surface BS. The semiconductor substrate SUB is made of n-type silicon. The semiconductor substrate SUB has a low-concentration n-type drift region NV. In the first embodiment, the n-type semiconductor substrate SUB itself configures the drift region NV. Note that the semiconductor substrate SUB may be a lamination body of an n-type silicon substrate and an n-type semiconductor layer grown on the n-type silicon substrate with phosphorus (P) being introduced by an epitaxial growth method. In this case, the low-concentration n-type semiconductor layer configures the drift region NV, and a high-concentration n-type silicon substrate configures a drain region ND.

The n-type drain region ND is formed on the semiconductor substrate SUB so as to reach a predetermined depth toward the upper surface TS of the semiconductor substrate SUB from the lower surface TS of the semiconductor substrate SUB. The drain region ND has a higher impurity concentration than that of the drift region NV.

Under the lower surface BS of the semiconductor substrate SUB, a drain electrode DE is formed. The drain electrode DE is made of, for example, a single-layer metal film such as an aluminum film, a titanium film, a nickel film, a gold film, or a silver film, or a lamination film obtained by laminating those metal films appropriately. The drain region ND and the drain electrode DE are formed throughout the cell region CR and the outer circumferential region OR. A drain potential is supplied to the semiconductor substrate SUB (drain region ND, drift region NV) from the drain electrode DE.

The trench CH is formed in the semiconductor substrate SUB so as to reach the predetermined depth toward the lower surface BS of the semiconductor substrate SUB from the upper surface TS of the semiconductor substrate SUB.

As shown by the A-A section of FIG. 4, the field plate electrode is formed in the trench CH via the insulation film IF1. The upper surface of the field plate electrode FP including the drawer portion FPa is lower than the upper surface TS of the semiconductor substrate SUB. That is, a position of the upper surface of the drawer portion FPa is the same as a position of the upper surface of the field plate electrode FP other than the drawer portion FPa. In addition, a position of the upper surface of the insulation film IF1 is lower than a position of the upper surface of the field plate electrode FP including the drawer portion FPa.

A gate insulation film GI is formed in the trench TR on the insulation film IF1. The insulation film IF2 is formed so as to cover the field plate electrode FP exposed from the insulation film IF1. On the field plate electrode FP, the gate electrode GE is formed via the insulation film IF2. Each of the field plate electrode FP and the gate electrode GE is made of, for example, a polycrystalline silicon film into which n-type impurities are introduced. In this addition, an impurity concentration of this polycrystalline silicon film is higher than an impurity concentration of the semiconductor substrate SUB (drift region NV).

In addition, a part of the gate electrode GE is also formed between the semiconductor substrate SUB and the field plate electrode FP and in a space surrounded by the insulation film IF1, the insulation film IF2, and the gate insulation film GI.

The insulation film IF1 formed between the is semiconductor substrate SUB and the field plate electrode FP. The insulation film IF2 is formed between the gate electrode GE and the field plate electrode FP. The gate insulation film GI is formed between the semiconductor substrate SUB and the gate electrode GE. By those films, the semiconductor substrate SUB, the gate electrode GE, and the field plate electrode FP are electrically insulated from one another. The insulation film IF1, the insulation film IF2, and the gate insulation film GI are each made of, for example, a silicon oxide film.

A p-type body region BP is formed in the semiconductor substrate SUB so as to reach the predetermined depth toward the lower surface BS of the semiconductor substrate SUB from the upper surface TS of the semiconductor substrate SUB. In the semiconductor substrate SUB, the p-type body region PB is formed. The depth from the upper surface TS of the semiconductor substrate SUB to the body region PB is shallower than the depth from the upper surface TS of the semiconductor substrate SUB to the trench CH. In the body region PB, an n-type source region NS is formed. The source region NS has a higher impurity concentration than that of the drift region NV.

On the upper surface TS of the semiconductor substrate SUB, an interlayer insulation film IL is formed so as to cover the trench TR. The interlayer insulation film IL is made of, for example, a silicon oxide film.

In the interlayer insulation film IL, the hole CH1 that penetrates through the interlayer insulation film IL and the source region NS and reaches the body region PB is formed. On a bottom portion of the hole CH1, a high-concentration diffusion region PR is formed in the body regio PB. The high-concentration diffusion region PR has a higher impurity concentration that that of the body region PB. The high-concentration diffusion region PR is provided to lower connection resistance to a plug PG and to prevent latch-up.

As shown by the B-B section of FIG. 4, the part of the field plate electrode FP configures the drawer portion FPa of the field plate electrode FP. The insulation film IF2 is formed so as to cover the drawer portion FPa exposed from the insulation film IF1. On the drawer portion FPa, the gate electrode GE is not formed. The body region PB is formed in the semiconductor substrate SUB adjacent to the drawer portion FPa via the insulation film IF1, but the source region NS is not formed in this body region PB.

In the interlayer insulation film IL, the hole CH3 that penetrates through the interlayer insulation film IL and to reach the drawer portion FPa is formed. Although being not illustrated here, the hole CH2 that penetrates through the interlayer insulation film IL and to reach the gate electrode GE is formed in the interlayer insulation film IL.

In each of the hole CH1, the hole CH2, and the hole CH3, the plug PG is embedded. The plug PG is made of, for example, a first barrier metal film and a first conductive film formed on the first barrier metal film. The first barrier metal film is made of, for example, a lamination film of a titanium film and a titanium nitride film. The first conductive film is, for example, a tungsten film.

On the interlayer insulation film IL, the source electrode SE is formed. Although being not illustrated here, the gate wiring GW is formed on the interlayer insulation film IL. The source electrode SE and the gate wiring GW are each made of, for example, a second barrier metal film and a second conductive film formed on the second barrier metal film. The second barrier metal film is, for example, a tungsten titanium film. The second conductive film is, for example, an aluminum alloy film to which copper or silicon is added.

The source electrode SE is electrically connected to the source region NS, the body region PB, and the high-concentration diffusion region PR via the plug PG formed in the hole CH1, and supplies a source potential to those impurity regions. In addition, the source electrode SE is electrically connected to the drawer portion FPa via the plug PG formed in the hole CH3, and supplies the source potential to the field plate electrode FP. The gate electrode GW is electrically connected to the gate electrode GE via the plug PG formed in the hole CH2, and supplies a gate potential to the gate electrode GE.

In the first embodiment, since the gate electrode GE is removed on the drawer portion FPa, the residue RS1 that causes the problem in the first consideration example is not formed. In addition, since the upper surface of the drawer portion FPa is lower than the upper surface TS of the semiconductor substrate SUB, the interlayer insulation film IL is formed also in the trench CH so as to cover the drawer portion FPa. The polishing processing by the CMP method is not performed to the interlayer insulation film IL. Therefore, an indent Ila is formed on the interlayer insulation film IL so that the upper surface of the interlayer insulation film IL located above the drawer portion FPa becomes lower than the upper surface of the interlayer insulation film IL at the other positions.

The hole CH3 penetrates through the indent ILa and is included in the intent Ila in the plan view. That is, a diameter of the indent Ila is wider than a diameter of the hole CH3, and spreads as approaching to the source electrode SE. In other words, the indent ILa functions as a part of the hole CH3, and the indent IL1 and the hole CH3 are one integrated hole. This one hole has a portion whose diameter becomes wider as approaching to the source electrode SE.

The plug PG is formed in the hole CH3 and the indent Ila (in the above one hole). Therefore, a width of the plug PG contacting with the source electrode SE is wider than a width of the plug PG contacting with the drawer portion FPa. In other words, a contact area with the source electrode SE and the plug PG is larger than a contact area with the drawer portion FPa and the plug PG. Since the contact area with the source electrode SE and the plug PG can be increased, the wiring resistance from the source electrode SE to the drawer portion FPa can be reduced.

### Method of Manufacturing Semiconductor Device

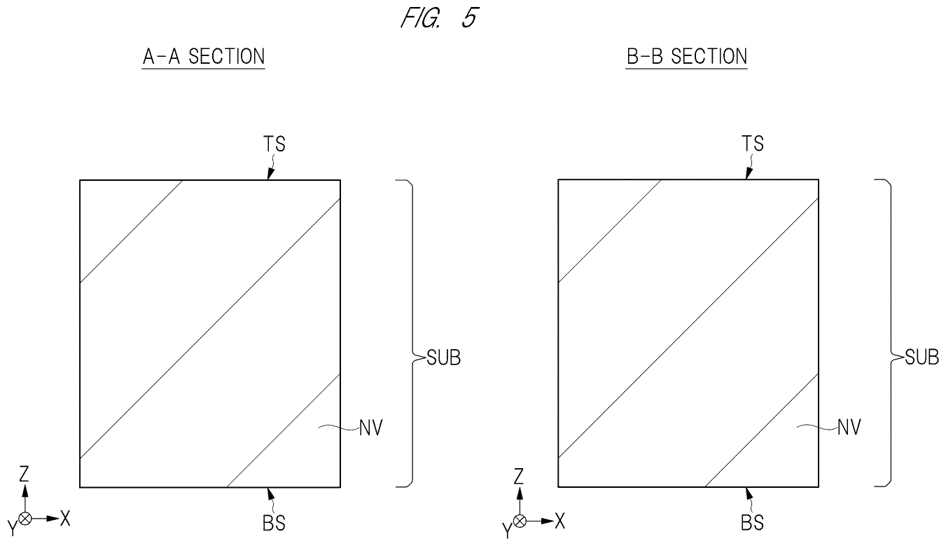

Hereinafter, by using FIG. 5 to FIG. 18, each manufacturing step included in a method of manufacturing the semiconductor device 100 according to the first embodiment will be explained.

Firstly, as shown in FIG. 5, the n-type semiconductor substrate SUB having the upper surface TS and the lower surface BS is prepared. As described above, the semiconductor device SUB may be the lamination body of the n-type silicon substrate and the n-type semiconductor layer formed on the silicon substrate by the epitaxial growth method.

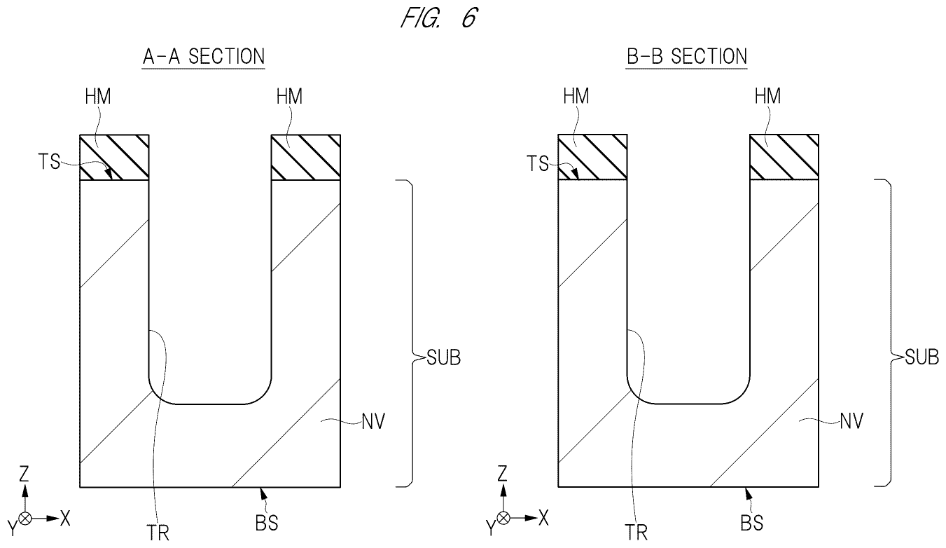

As shown in FIG. 6, the trench TR is formed in the semiconductor device 100 so as to reach the predetermined depth from the upper surface TS of the semiconductor substrate SUB to the lower surface BS of the semiconductor substrate SUB.

Firstly, for example by a Chemical Vaper Deposition (CVD) method, for example a silicon oxide film is formed on the semiconductor substrate SUB. Next, by a photolithography technique and an anisotropic etching processing, a hard mask HM is formed by patterning the above silicon oxide film. Next, by using the hard mask HM as a mask to perform the anisotropic etching processing, the trench TR is formed in the semiconductor substrate SUB. Then, for example by a wet etching processing using solution containing hydrofluoric acid, the hard mask HM is removed.

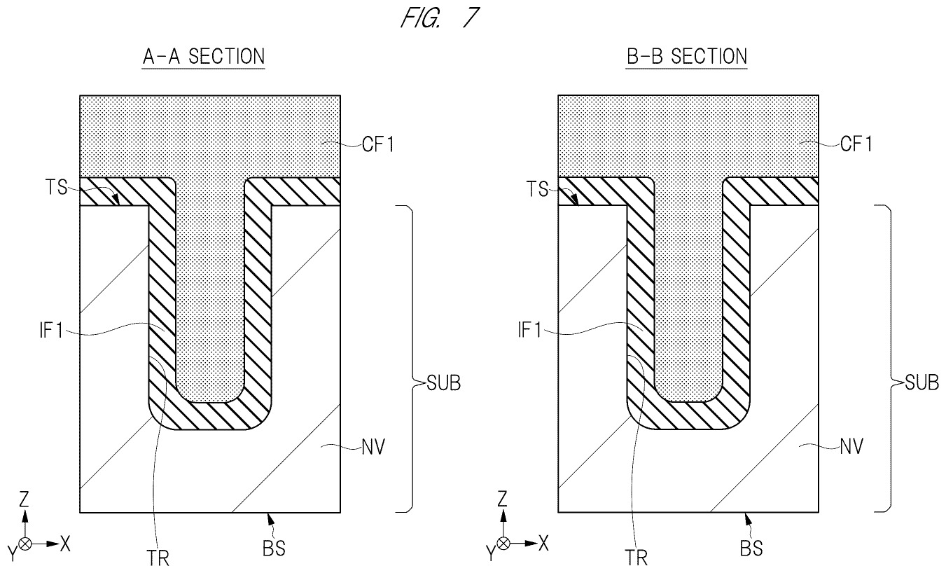

As shown in FIG. 7, firstly, in the trench CH and on the upper surface TS of the semiconductor substrate SUB, the insulation film IF1 is formed. The insulation film IF1 is a silicon oxide film formed by, example, a film forming processing using the CVD method. Note that the insulation film IF1 may be a lamination film made of a first silicon oxide film formed by the thermal oxidation processing, and a second silicon oxide film formed on the first silicon oxide film by the film forming processing using the CVD method.

Next, the conductive film CF1 is formed on the insulation film IF1 by, for example, the film forming processing using the CVD method so as to fill the trench TR. The conductive film is, for CF1 example, an n-type polycrystalline silicon film.

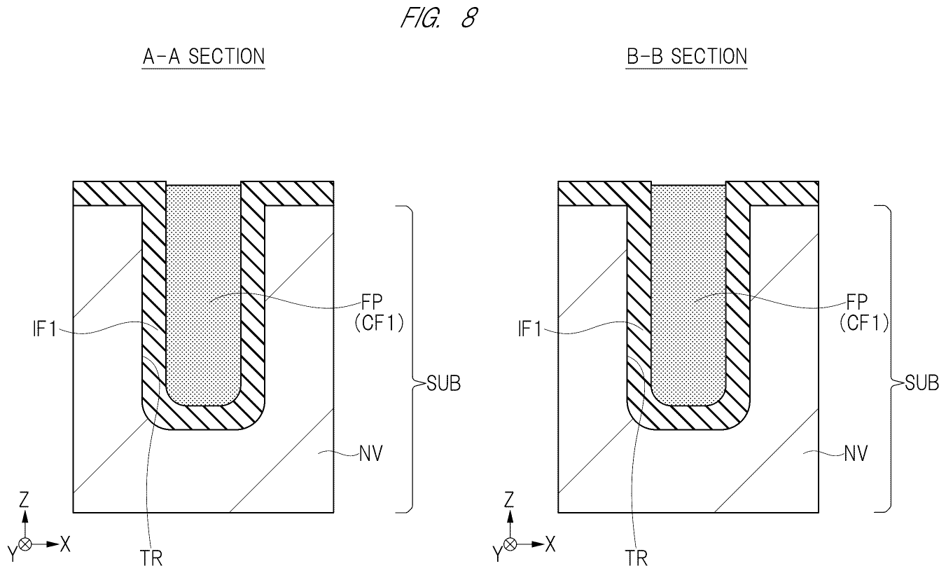

As shown in FIG. 8, for example by the polishing processing using a Chemical Mechanical Polishing (CMP) method, the conductive film CF1 left in the trench CH is formed as the field plate electrode FP by removing the conductive film IF1 located outside the trench CH. This polishing processing is performed by using, as an etching stopper, the insulation film IF1 located outside the trench CH.

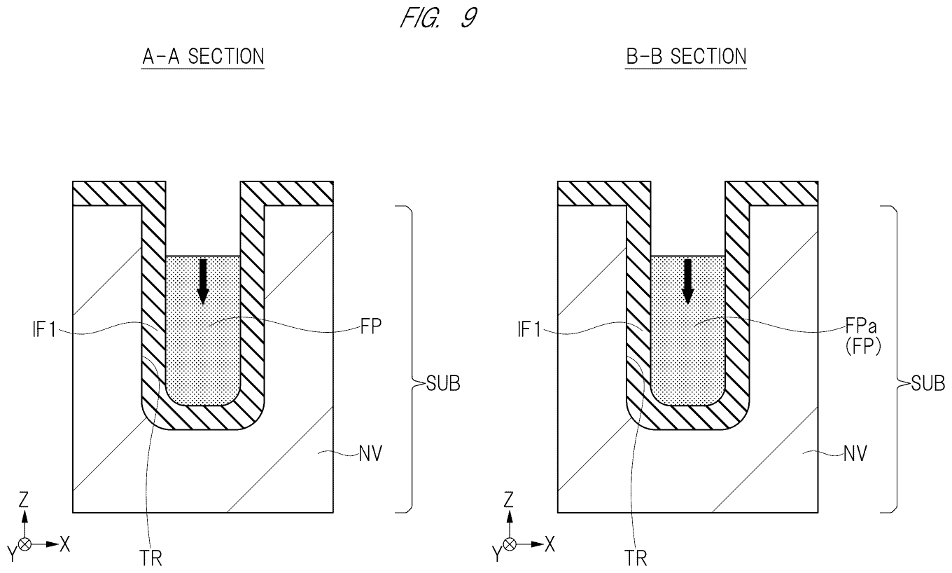

As shown in FIG. 9, for example by performing the anisotropic etching processing using SF₆ gas on the condition that the field plate electrode FP is more easily etched than the insulation film IF1, the field plate electrode FP is recessed toward the bottom portion of the trench TR.

Note that in this anisotropic etching processing, a resist pattern is not used. Accordingly, by this anisotropic etching processing, the entire field plate electrode FP is recessed. Therefore, the upper surface of the field plate electrode FP including the drawer portion FPa becomes lower than the upper surface TS of the semiconductor substrate SUB. In addition, a position of the upper surface of the drawer portion FPa is the same as a position of the upper surface of the field plate electrode FP other than the drawer portion FPa.

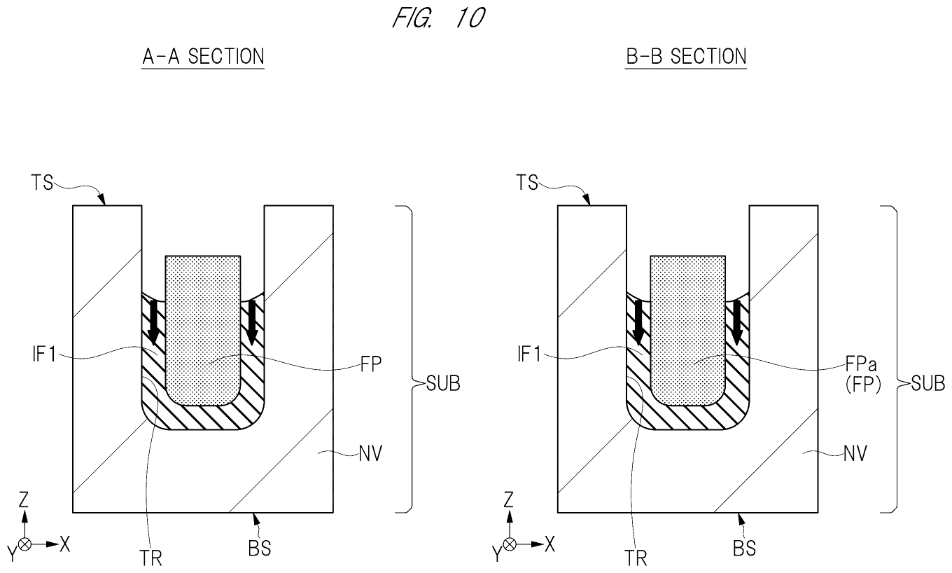

As shown in FIG. 10, the isotropic etching processing, which uses the solution containing hydrofluoric acid is performed to the insulation film IF1. Consequently, the insulation film IF1 located on the upper surface TS of the semiconductor substrate SUB is removed and, simultaneously, the insulation film IF1 located in the trench CH is recessed toward the bottom portion of the trench CH so that the position of the upper surface of the insulation IF1 located in the trench CH becomes lower than the position of the upper surface of the field plate electrode FP.

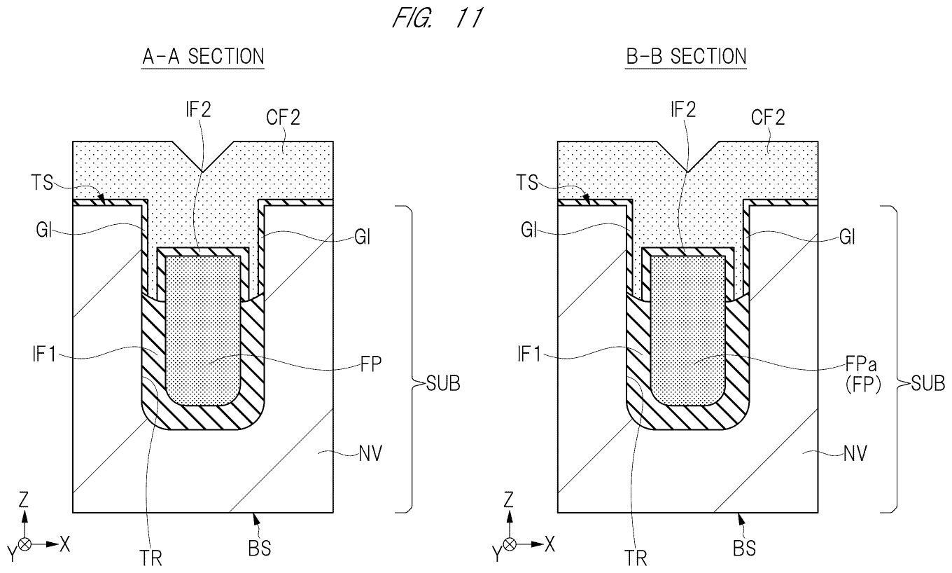

As shown in FIG. 11, firstly, by performing the thermal oxidation processing, the gate insulation film GI is formed on the upper surface TS of the semiconductor substrate SUB and in the trench CH located on the insulation film IF1 and, simultaneously, the insulation film IF2 is formed so as to cover the field plate electrode FP exposed from the insulation film IF1. Next, for example by the deposition procession using the CVD method, a conductive film CF2 is formed on the gate insulation film GI and the insulation film IF2 so as to fill the trench CH. The conductive film CF2 is, for example, a polycrystalline silicon film.

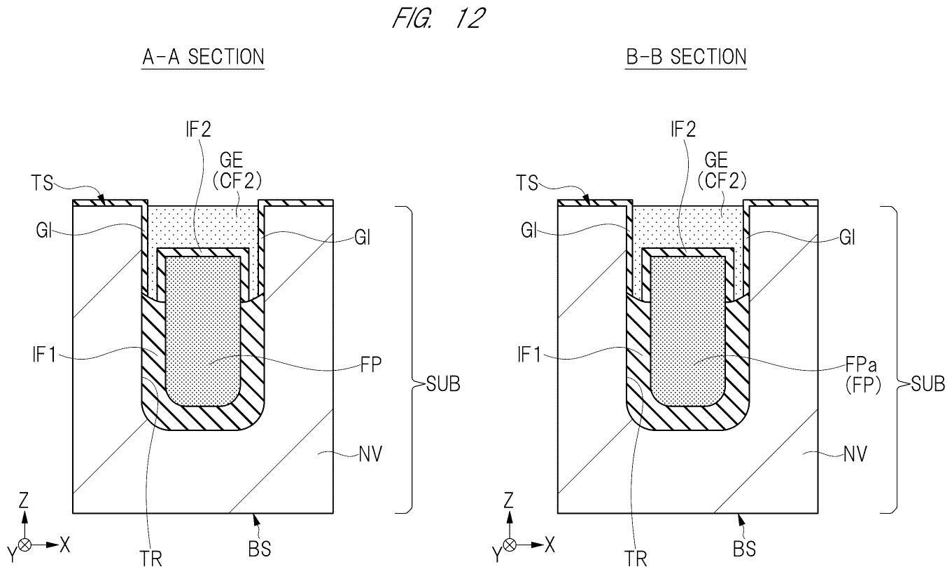

As shown in FIG. 12, the polishing processing using the CVD method is performed to the conductive film CF2. By removing the conductive film CF2 located outside the trench CH, the conductive film CF2 left in the trench CH on the field plate electrode FP is formed as the gate electrode GE. At this time point, the position of the upper surface of the gate electrode GE becomes almost the same as the position of the upper surface TS of the semiconductor substrate SUB.

Note that this polishing processing uses, as an etching stopper, the gate insulation film GI located outside the trench CH. By using solution containing NH₄OH and slurry containing colloidal silica, the conductive film CF2 can be polished on the condition that a selection ratio to the gate insulation film GI is high.

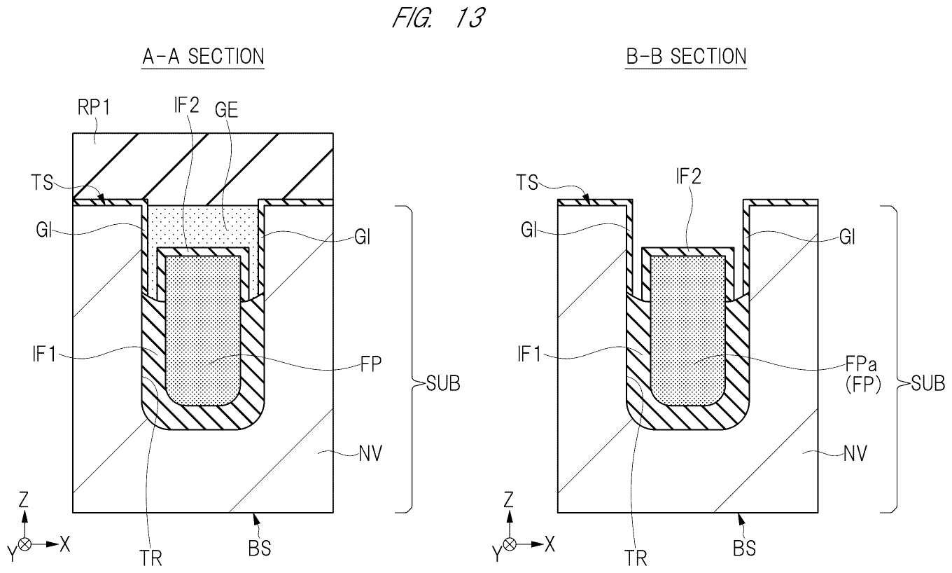

As shown in FIG. 13, firstly, the resist pattern RP1 selectively covering a portion, which covers the field plate electrode FP other than the drawer portion FPa, in the gate electrode GE is formed. The gate electrode GE located on the drawer portion FPa is exposed from the resist pattern RP1. Next, by performing the anisotropic etching processing using the resist pattern RP1 as a mask, the portion, which covers the drawer portion FPa, in the gate electrode GE is selectively removed. Next, the resist pattern RP1 is removed by the ashing processing.

This anisotropic etching processing is performed on the condition that the insulation film IF1, the insulation film IF2, and the gate insulation film GI are hardly etched and that the gate electrode GE is easily etched. In addition, an over etching is performed so that the gate electrode GE formed between the drawer portion FPa and the semiconductor substrate SUB and in a space surrounding the insulation film IF1, the insulation film IF2, and the gate insulation film GI is completely removed. Consequently, the residue RS1 causing the problem in the first consideration example is not formed.

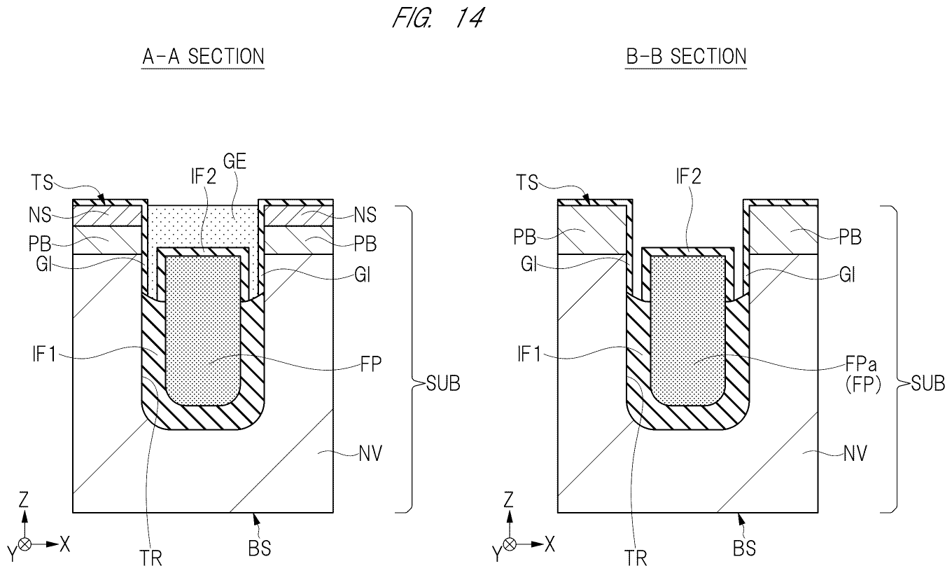

As shown in FIG. 14, firstly, by introducing, for example, boron (B) by the photolithography technique and the ion implantation method, the p-type body region PB is selectively formed in the semiconductor substrate SUB. The body region PB is formed so as to become shallower than the depth of the trench TR.

Next, by introducing, for example, arsenic (As) by the photolithography technique and the ion implantation method, the n-type source region NS is selectively formed in the body region PB of the cell region CR. Note that in the body region PB adjacent to the drawer portion FPa, the source region NS is not formed. Then, by performing the heating processing to the semiconductor substrate SUB, the impurities contained in the source region NS and the body region PB are activated.

Note that before forming the interlayer insulation film IL in the next manufacturing step, the gate insulation film GI formed on the upper surface TS of the semiconductor substrate SUB may be removed.

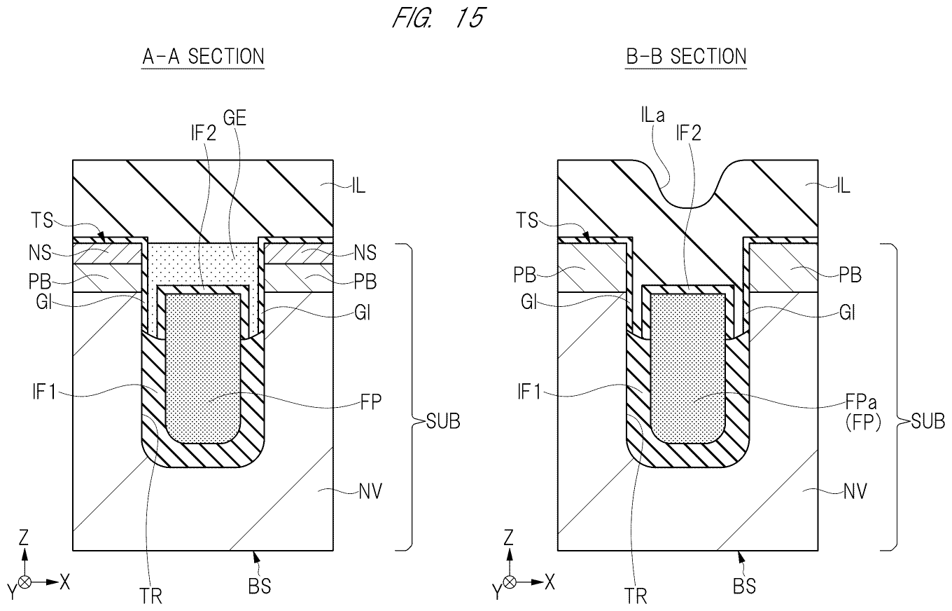

As shown in FIG. 15, for example by the deposition processing using the CVD method, the interlayer insulation film IL is formed on the upper surface TS of the semiconductor substrate SUB so as to cover the trench CH. As shown by the A-A section of FIG. 15, since the position of the upper surface of the gate electrode GE is almost the same as the position of the upper surface of the semiconductor substrate SUB, the upper surface of the interlayer insulation film IL located above the gate electrode GE is almost flat.

Meanwhile, as by the B-B section of FIG. 15, since the gate electrode GE is removed on the drawer portion FPa, the interlayer insulation film IL is formed also in the trench CH so as to cover the drawer portion FPa via the insulation film IF2. Therefore, the indent ILa is formed in the interlayer insulation film IL so that the upper surface of the interlayer insulation film IL located above the drawer portion FPa becomes lower than the upper surface the upper surface of other portions of the interlayer insulation film IL.

Note that in the first embodiment, the polishing processing by the CMP method is not performed to the interlayer insulation film IL. Accordingly, under a state in which the indent ILa is formed on the insulation film IL, the subsequent manufacturing step is performed.

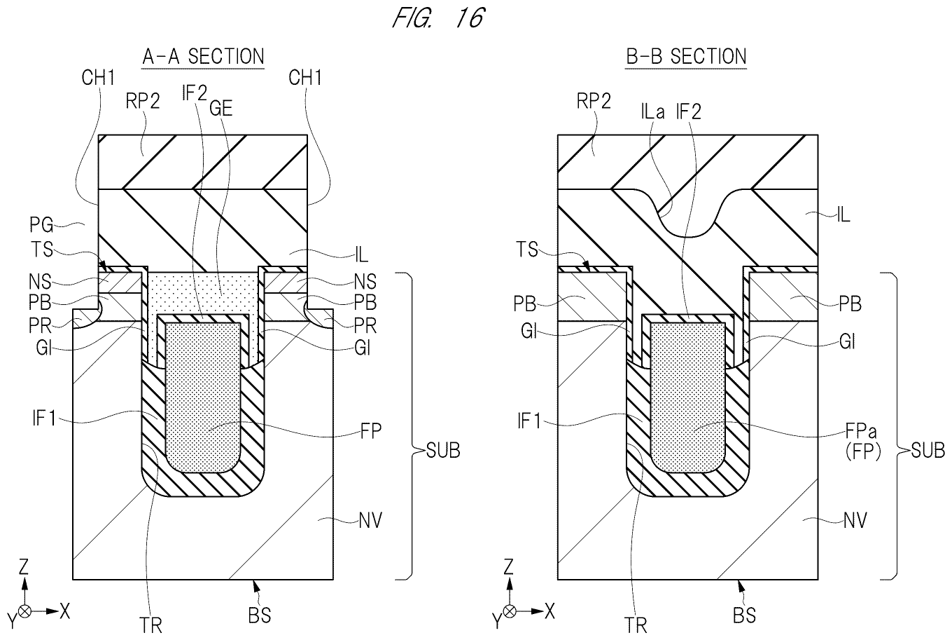

As shown in FIG. 16, the hole CH1 is formed in the interlayer insulation film IL. Firstly, the resist pattern RP2 having a pattern for opening the semiconductor substrate SUB in which the source region NS is formed is formed. Next, by performing the anisotropic etching processing using the resist pattern RP2 as a mask, the hole CH1 that penetrates through the interlayer insulation film IL and the source region NS and that reaches the inside of the body region PB is formed. Next, by introducing, for example, boron (B) to the body region PB in the bottom portion of the hole CH1 by the ion implantation method, the p-type high-concentration diffusion region PR is formed. Next, the resist pattern RP2 is removed by the ashing processing.

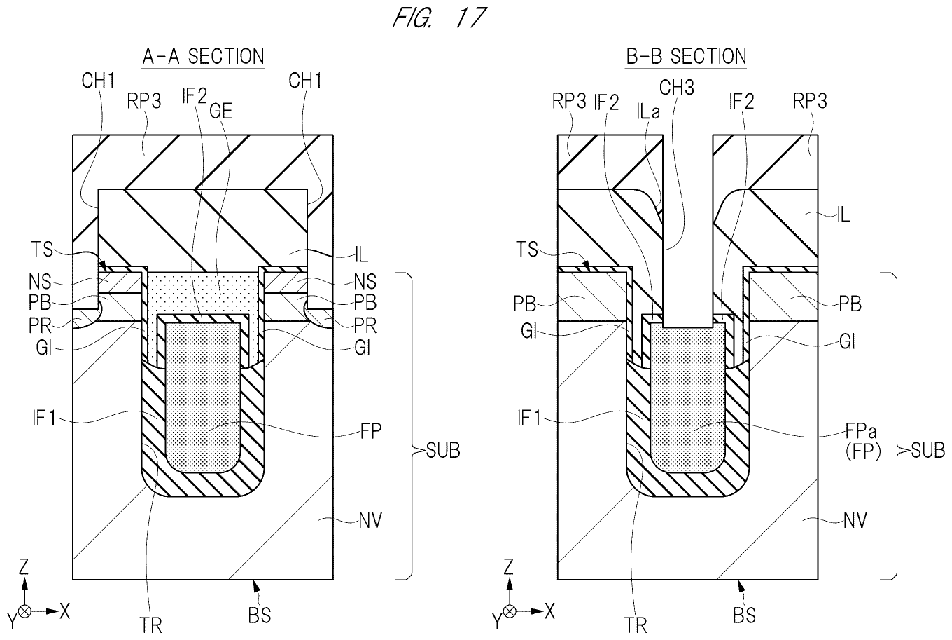

As shown in FIG. 17, the hole CH2 and the hole CH3 are formed in the interlayer insulation film IL. Here, although the hole CH2 is not illustrated, the hole CH2 is also formed during forming the holes CH3.

Firstly, a resist pattern RP3 having patterns for opening on the drawer portion FPa in the cell region CR and opening on the gate electrode GE in the outer circumferential region OR is formed. Next, by performing the anisotropic etching processing using the resist pattern RP3 as a mask, the hole CH3 reaching the drawer portion FPa and the hole CH2 reaching the gate electrode GE are formed. The hole CH3 is formed at a position including the indent ILa in the plan view, and communicates with the indent ILa. Next, by the ashing processing, the resist pattern RP3 is removed.

Note that it does not matter which comes first about order of forming the hole CH1 and order of forming the hole CH2 and hole CH3. In addition, the hole CH1, and the hole CH2, and hole CH3 may be formed simultaneously. In this case, the drawer portion FPa exposed in the bottom portion of the hole CH3 is excavated as deep as the bottom portion of the hole CH1 on the basis of the upper surface TS of the semiconductor substrate SUB. In addition, the gate electrode GE exposed in the bottom portion of the hole CH2 is also excavated as deep as. At this time, a thickness of the gate electrode GE needs to be previously formed thick so that the bottom portion of the hole CH2 does not contact with the insulation film IF2.

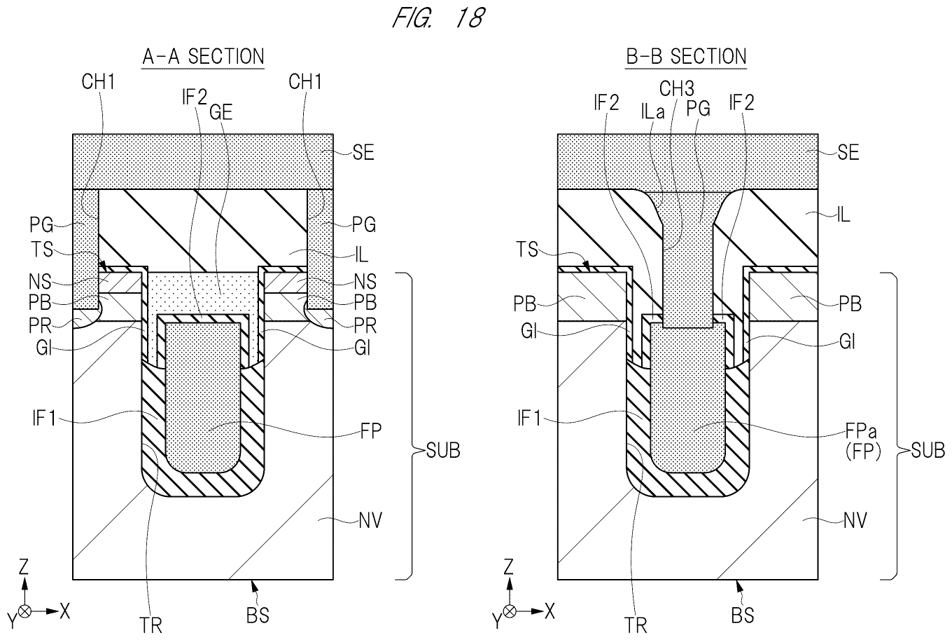

As shown in FIG. 18, the plug PG is formed in each of the holes CH1, the hole CH2, and the hole CH3, and the source electrode SE and the gate wiring GW are formed on the interlayer insulation film IL. Although the gate wiring GW is not illustrated here, the gate wiring GW is also formed during a step of forming the source electrode SE.

Firstly, by the film forming processing using the spattering method or the CVD method, the first barrier metal film is formed in each of the hole CH1, the hole CH2, and the hole CH3 and on the interlayer insulation film IL. The first barrier metal film is made of, for example, a lamination film of a titanium nitride film and a titanium film. Next, by the film forming processing using the CVD method, the first conductive film is formed on the first barrier metal film. The first conductive film is made of, for example, a tungsten film. Next, by the polishing processing using the CMP method, the first barrier metal film and the first conductive film that are formed outside each of the hole CH1, the hole CH2, and the hole CH3 are removed. Consequently, the plug PG made of the first barrier metal film and the first conductive film is formed so as to fill each of the hole CH1, the hole CH2, and the hole CH3.

Note that the plug PG connected to the drawer portion FPa is formed in the hole CH3 and the indent ILa. The diameter of the indent ILa is wider than the diameter of the hole CH3 and the diameter of the indent ILa becomes wider as going upward, so that an aspect ratio becomes low in comparison with a case of no indent ILa. Therefore, the first barrier metal film and the first conductive film are easily embedded at the inside of the hole CH3.

Next, by the film forming processing using the spattering method, a second barrier metal film is formed on the interlayer insulation film IL. The second barrier metal film is, for example, a titanium tungsten film. Next, by the film forming processing using the spattering method, a second conductive film is formed on the second barrier metal. The second conductive film is, for example, an aluminum alloy film to which copper and silicon are added. Next, by patterning the second barrier metal film and the second conductive film, the source electrode SE and the gate wiring GW are formed.

Next, although being not illustrated here, for example by an application method, the protection film made of, for example, a polyimide film is formed on the source electrode SE and the gate wiring GW. By forming the opening in a part of the protection film, regions to become a source pad SP and a gate pad GP in the source electrode SE and the gate wiring GW are exposed.

Then, through the following manufacturing step, a structure body shown by FIG. 4 is obtained. Firstly, the lower surface BS of the semiconductor device SUB is polished as needed. Next, by introducing, for example, arsenic (As) and the like into the lower surface BS of the semiconductor substrate SUB by the ion implantation method, an n-type drain electrode ND is formed. Next, by the film forming processing using the spattering method, a drain electrode DE is formed under the lower surface BS of the semiconductor substrate SUB.

### Method of Manufacturing Semiconductor Device in Second Consideration Example

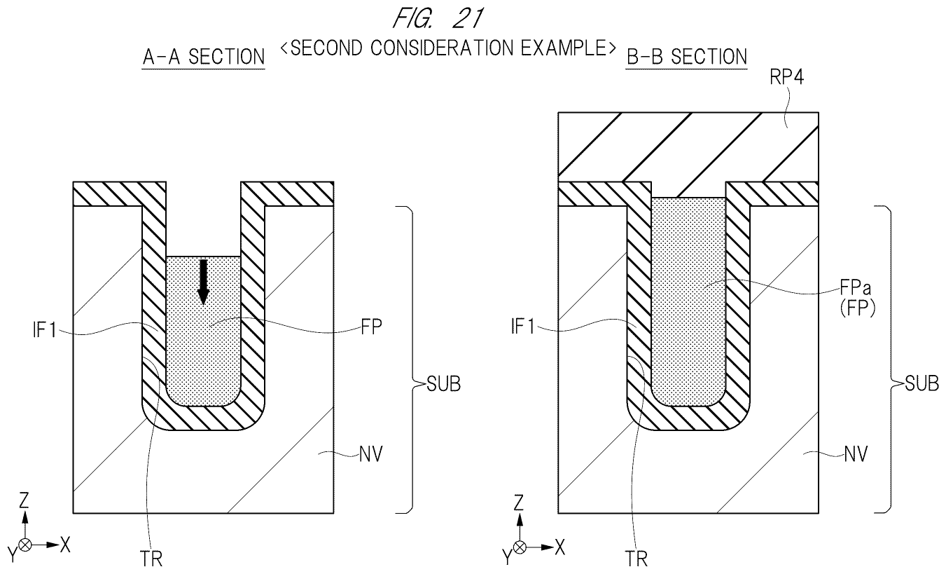

Hereinafter, by using FIG. 21 to FIG. 31, a method of manufacturing a semiconductor device according to a second consideration example will be explained. The second consideration example is a manufacturing method based on a technique disclosed in Patent Document 1, and is a manufacturing method considered by the inventor of the present application in order to remove the residue RS1 caused as the problem in the first consideration example.

The method of manufacturing the semiconductor device in the second consideration example are the same in FIG. 5 to FIG. 8 as the method of manufacturing the semiconductor device in the first consideration example. FIG. 21 shows a manufacturing step subsequential to FIG. 8.

As shown in FIG. 21, firstly, a resist pattern RP4 selectively covering one portion of the field plate electrode FP is formed. Next, by using the resist patten RP4 as a mask, the anisotropic etching processing is performed to the other portion of the field plate electrode FP. That is, as shown by the A-A section of FIG. 21, the other portion of the field plate electrode FP exposed from the resist pattern RP4 is selectively recessed toward the bottom portion of the trench TR. One portion of the field plate electrode FP not recessed becomes the drawer portion FPa. Next, by the ashing processing, the resist pattern RP4 is removed.

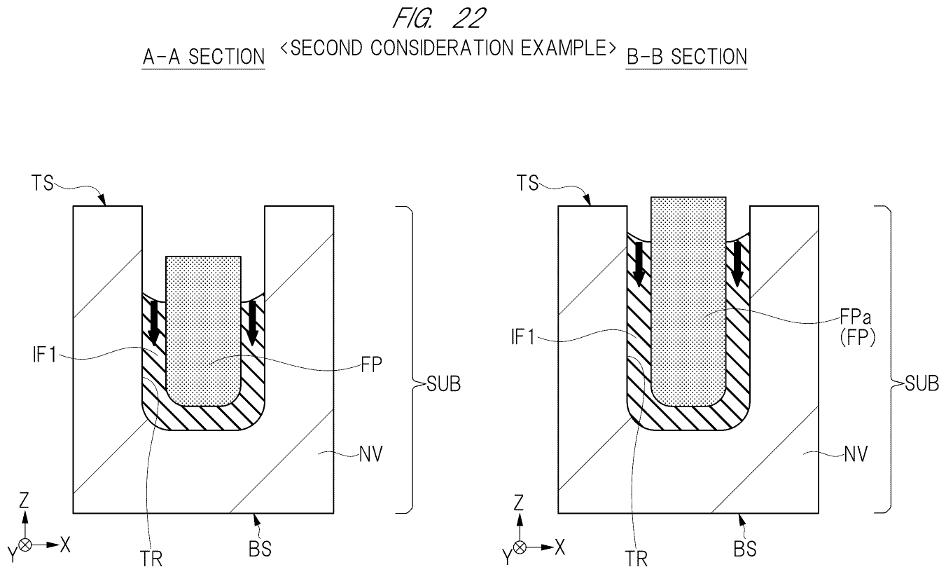

As shown in FIG. 22, the isotropic etching processing using the solution containing hydrofluoric acid is performed to the insulation film IF1. Consequently, the insulation film IF1 located on the upper surface TS of the semiconductor substrate SUB is removed and, simultaneously, the insulation film IF1 located in the trench CH is recessed toward the bottom portion of the trench TR. At this time point, the upper surface of the drawer portion FPa becomes higher than the upper surface TS of the semiconductor substrate SUB.

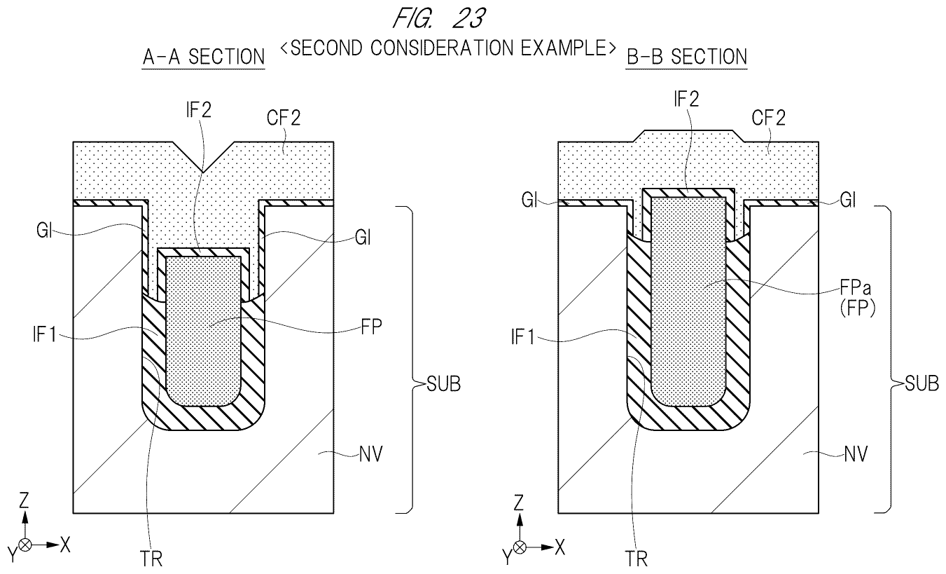

As shown in FIG. 23, firstly, by performing the thermal oxidation processing, the gate insulation film GI is formed in the trench TR located on the insulation film IF1 and, simultaneously, the insulation film IF2 is formed so as to cover the field plate electrode FP exposed from the insulation film IF1. Next, for example by the film forming processing using the CVD method, the conductive film CF2 is formed on the gate insulation film GI and the insulation film IF2.

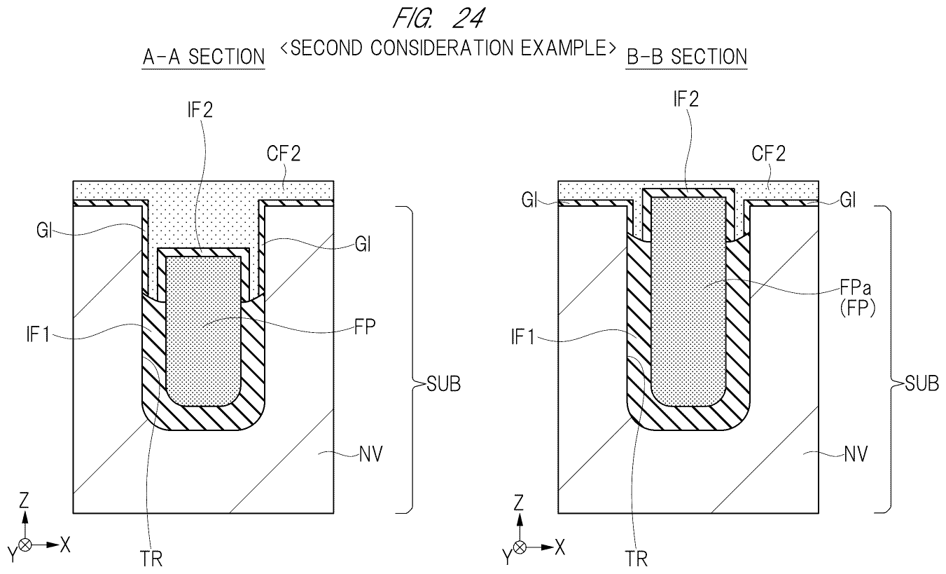

As shown in FIG. 24, the polishing processing using the CMP method is performed to the conductive film CF2. Here, since the position of the upper surface of the drawer portion is high, the entire conductive film CF2 formed outside the trench TR cannot be removed only by the polishing processing. Accordingly, by adjusting a polishing time, a part of the conductive film CF2 is polished so as not to polish the drawer portion FPa.

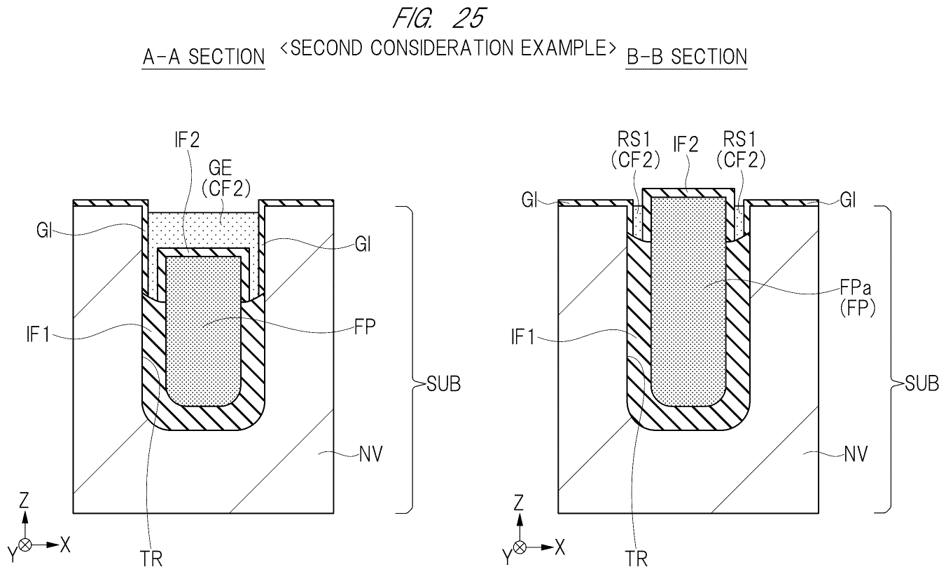

As shown in FIG. 25, by performing the anisotropic etching processing to the conductive film CF2 after the polishing processing, the conductive film CF2 formed outside the trench TR is removed. Consequently, the conductive film CF2 left in the trench TR on the field plate electrode FP is formed as the gate electrode GE.

Note that the anisotropic etching processing is performed by over etching in order to completely remove the conductive film CF2 formed outside the trench TR. Therefore, as shown by the A-A section of FIG. 25, the position of the upper surface of the gate electrode GE becomes lower than the position of the upper surface TS of the semiconductor substrate SUB.

Here, as shown by the B-B section of FIG. 25, the residue RS1 of the conductive film CF2 may be left on a side surface of the drawer portion FPa via the insulation film IF2 by this anisotropic etching processing. In order to remove the residue RS1, the anisotropic processing can further be continued. However, since the gate electrode GE is also subjected to the anisotropic etching processing, the thickness of the gate electrode GE becomes thin and the gate electrode GE on the field plate electrode FP may disappear.

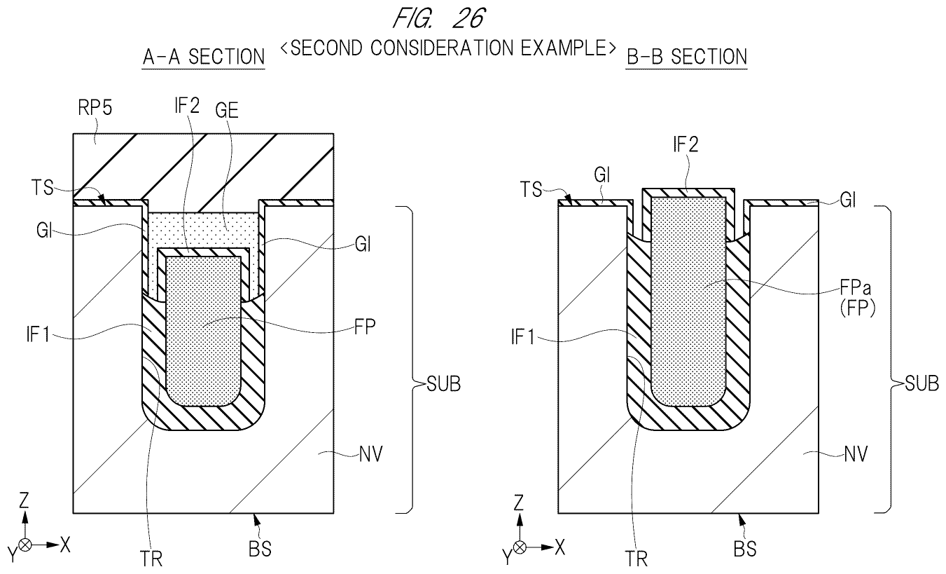

Therefore, as shown in FIG. 26, firstly, a resist pattern RP5 having a pattern for selectively opening the drawer portion FPa in the field plate electrode FP is formed on the upper surface TS of the semiconductor substrate SUB. The field plate electrode FP other than the drawer portion FPa is covered with the resist pattern RP5. Note that the resist pattern RP5 of FIG. 26 has the same pattern as the resist pattern RP1 of FIG. 13.

Next, by using the resist pattern RP5 as a mask, the anisotropic etching processing is performed to the residue RS1, and the residue RS1 is removed.

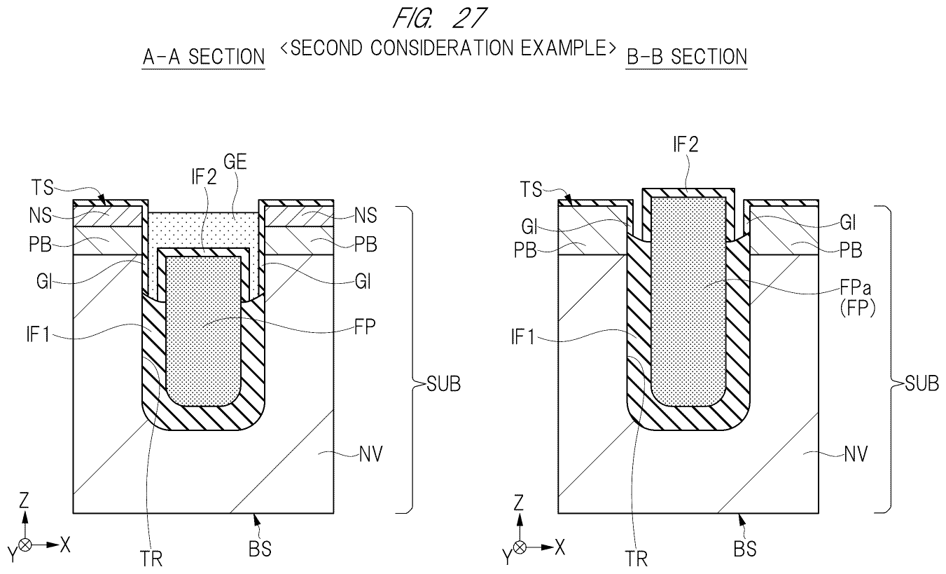

As shown in FIG. 27, by the same method as the method explained in FIG. 14, the p-type body region PB is selectively formed in the semiconductor substrate SUB, the n-type source region NS is selectively formed in the body region PB of the cell region CR.

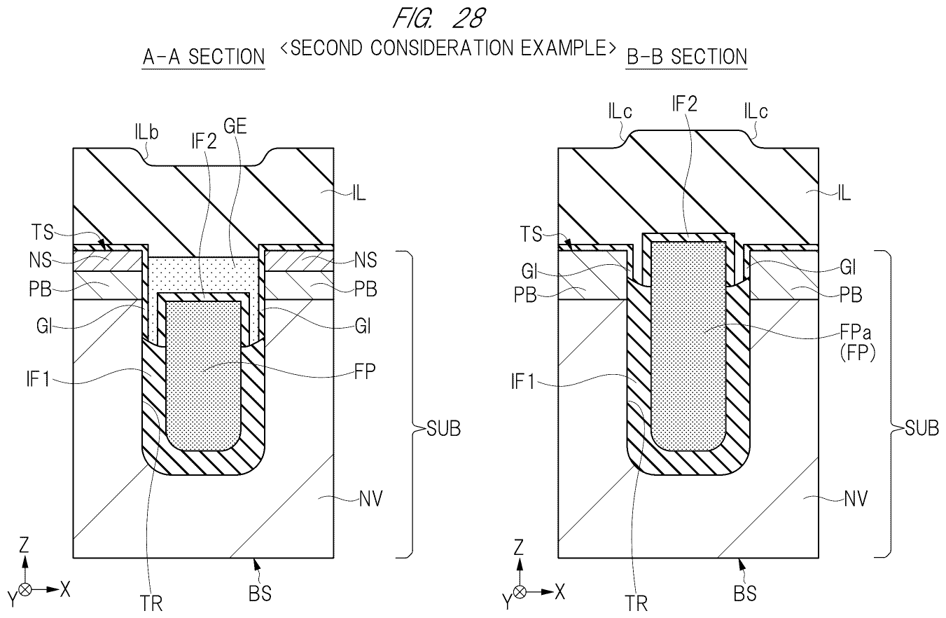

As shown in FIG. 28, for example by the film forming processing using the CVD method, the interlayer insulation film IL is formed on the upper surface TS of the semiconductor substrate SUB so as to cover the trench CH. As shown by the A-A section of FIG. 28, since the upper surface of the gate electrode GE becomes lower than the upper surface TS of the semiconductor substrate SUB, an indent ILb is formed on the interlayer insulation film IL located above the gate electrode GE.

In addition, as shown by the B-B section of FIG. 28, the upper surface of the drawer portion FPa becomes higher than the upper surface TS of the semiconductor substrate SUB, the upper surface of the interlayer insulation film IL located above the drawer portion FPa rises and an indent ILc is formed around its periphery.

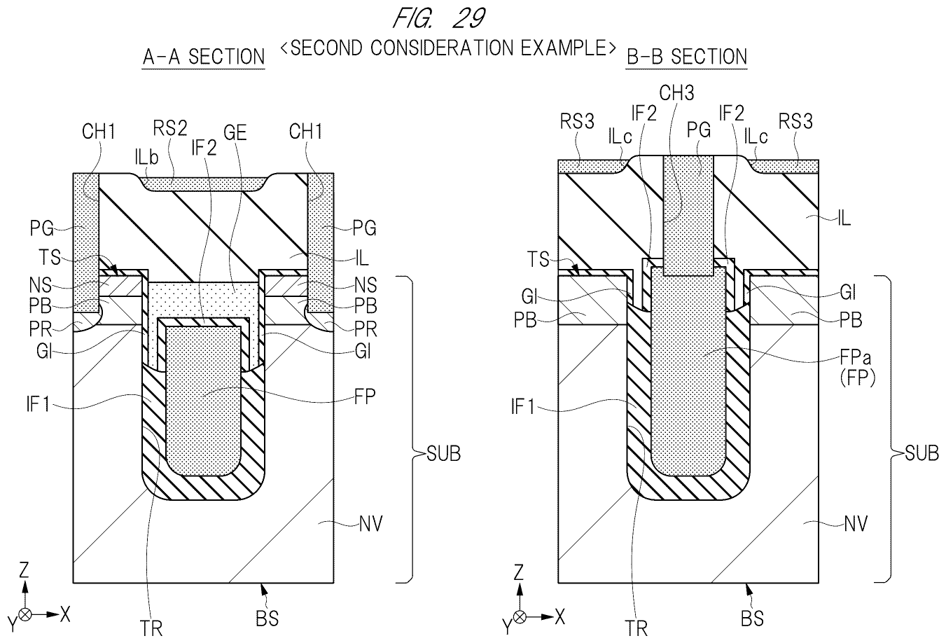

As shown in FIG. 29, if the polishing processing by the CMP method is not performed to the interlayer insulation film IL, a material configuring the plug PG is left as a residue RP2 in the indent ILb and is left as a residue RS3 in the indent ILc when the plug PG is formed. Therefore, the residue RS2 and the residue RS3 may function as a leak path connecting the source electrode GE and the gate wiring GW.

The residue RS2 left in the indent ILb extends in the Y direction along the gate electrode GE. Therefore, the residue RS2 may be electrically connected to the gate wiring GW via the hole CH2 (see FIG. 2 and FIG. 3).

The residue RS3 left in the indent ILc is located above the semiconductor substrate SUB adjacent to the drawer portion FPa in the X direction. Accordingly, even if the residue RP3 exists in the cell region CR, does not matter particularly, but the source electrode GE and the gate wiring GW may be electrically connected to each other by the residue RS3 in the outer circumferential region OR (see FIG. 1).

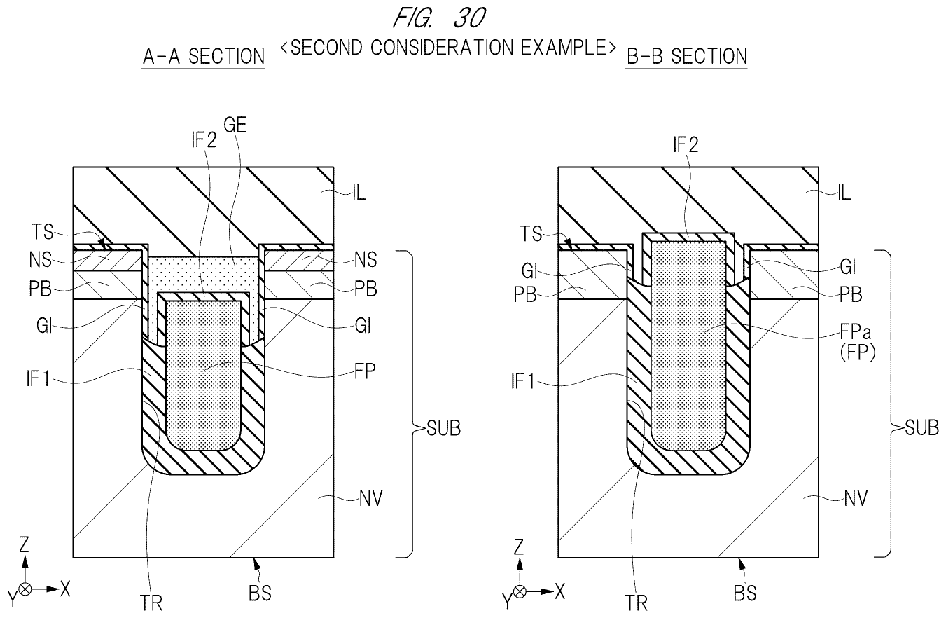

Accordingly, in the second consideration example, as shown in FIG. 30, by performing the polishing processing by the CMP method to the interlayer insulation film IL, the indent ILb and the indent ILc are eliminated and the upper surface of the interlayer insulation film IL is flattened.

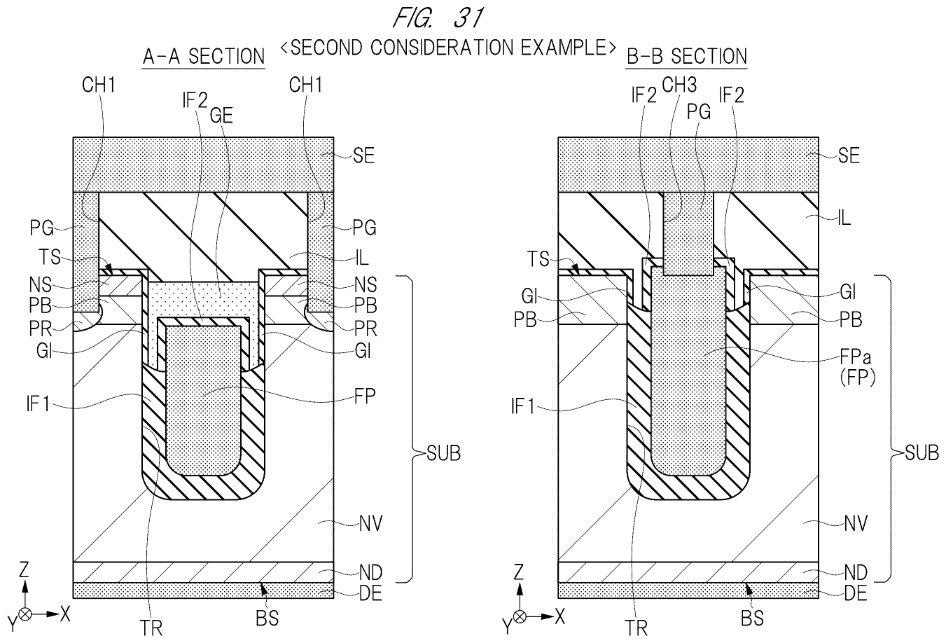

Then, as shown in FIG. 31, by the same methods as the methods shown by FIG. 16 to FIG. 18, the hole CH1, the hole CH2, the hole CH3, the plug PG, the source electrode SE, the gate wiring GW, the drain region ND, and the drain electrode DE are formed.

### Comparison With First Embodiment and Second Consideration Example

Also by the second consideration example, the residue RS1 causing the problem of the first consideration example can be removed. However, in the second consideration example, the resist pattern RP1 needs to be formed in order to remove the residue RS1, and the anisotropic etching processing needs to be performed by using the resist pattern RP1 as a mask. Therefore, there is a problem about an increase in the manufacturing costs.

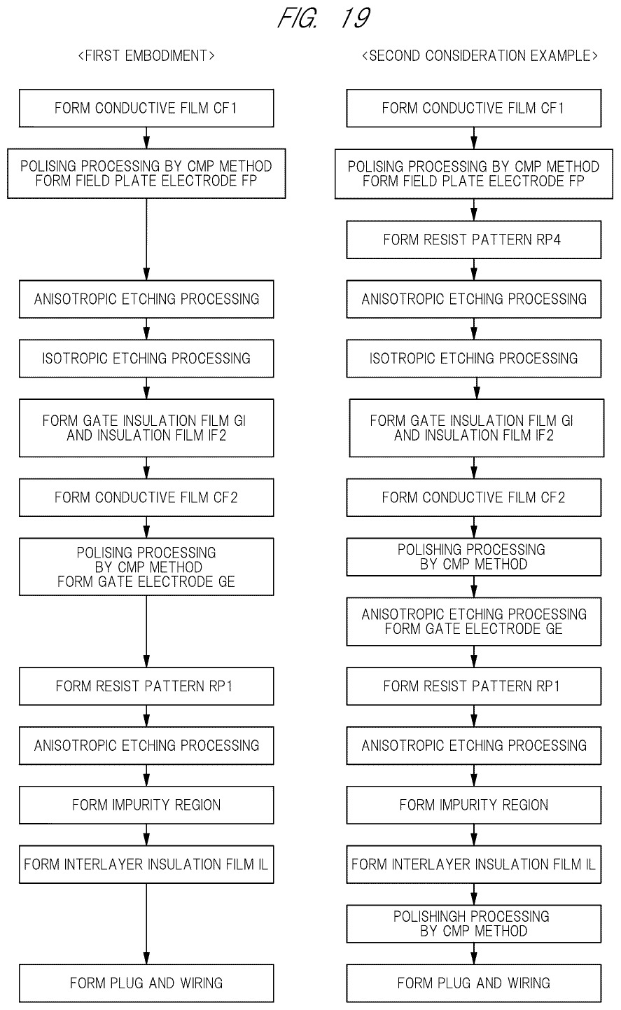

According to the first embodiment, the occurrence of the residue RS1 can be suppressed and, simultaneously, the semiconductor device 100 can be manufactured by the manufacturing step less than that of the second consideration example. FIG. 19 is a flowchart obtained by comparing each manufacturing step of the first embodiment and each manufacturing step of the second consideration example.

Firstly, in the second consideration example, as shown in FIG. 21, by performing the anisotropic etching processing using the resist pattern RP4, the field plate electrode FP other than the drawer portion FPa is recessed.

In contrast, in the first embodiment, as shown in FIG. 9, by performing the anisotropic etching processing without using the resist pattern RP4, the entire field plate electrode GE including the drawer portion FPa is recessed. Therefore, in the first embodiment, the manufacturing costs for forming the resist pattern RP4 can be reduced.

Next, in the second consideration example, as shown in FIG. 24 and FIG. 25, the polishing processing using the CMP method and the anisotropic etching processing become necessary in order to form the gate electrode GE from the conductive film CF2. Then, as shown in FIG. 26, the anisotropic etching processing is performed in order to remove the residue RS1.

In contrast, in the first embodiment, as shown by the manufacturing step of FIG. 9, the upper surface of the field plate electrode FP including the drawer portion FPa becomes lower than the upper surface of the semiconductor substrate SUB. Therefore, as shown in FIG. 12, the gate electrode GE can be formed from the conductive film CF2 only by the polishing processing using the CMP method. Since the anisotropic etching processing for forming the gate electrode GE can be omitted, the manufacturing costs can be reduced.

Then, as shown in FIG. 13, the first embodiment and the second consideration example are the same about a point of performing anisotropic etching processing using the resist pattern RP1. However, in the first embodiment, by the one-time anisotropic etching processing, the gate electrode GE located on the drawer portion FPa can be removed and, simultaneously, the occurrence of the residue RS1 can be suppressed.

In addition, in the second consideration example, variations of thickness of the conductive film CF2 in the wafer surface occur at a time of forming the conductive film CF2. Further, also at a time of the polishing processing of the conductive film CF2, the part of the conductive film CF2 is polished by adjusting the polishing time, so that the variations of the thickness of the conductive film CF2 in the wafer surface occur. Moreover, by the anisotropic etching processing, the gate electrode GE is formed from the conductive film CF2, so that the variations of the thickness of each gate electrode GE in the wafer surface occur. That is, the variations occur at the position of the upper surface of each gate electrode GE in the wafer surface. Accordingly, since the variations of the thickness of the conductive film CF2 (each gate electrode GE) in the wafer surface occur in three stages, the characteristics of each MOSFET easily becomes more variable.

In contrast, in the first embodiment, the variations of the thickness of the conductive film CF2 in the wafer surface occur at the time of forming the conductive film CF2, but the polishing processing of the conductive film CF2 is performed by using, as a stopper, the gate insulation film GI located outside the trench TR. Accordingly, the variations of the thickness of each gate electrode GE hardly occur. That is, the position of the upper surface of each gate electrode GE in the wafer surface is almost the same. Therefore, the variations of the characteristics of each MOSFET can be suppressed.

Next, in the second consideration example, due to the upper surface of the gate electrode GE being lower than the upper surface TS of the semiconductor substrate SUB and the upper surface of the drawer portion FPa being higher than the upper surface TS of the semiconductor substrate SUB, the indent ILb and the indent ILc are formed in the interlayer insulation film IL as shown by FIG. 28 and FIG. 29. Since the indent ILb and the indent ILc may become the leak paths, the polishing processing by the CMP method needs to be performed to the interlayer insulation film IL as shown by FIG. 30.

In contrast, in the first embodiment, the position of the upper surface of the gate electrode GE is almost the same as the position of the upper surface TS of the semiconductor substrate SUB, and the upper surface of the drawer portion FPa is lower than the upper surface TS of the semiconductor substrate SUB. Therefore, as shown in FIG. 15, in the interlayer insulation film IL, the indent ILb and the indent ILc are not formed, but the indent ILa is formed above the drawer portion FPa. The indent ILa does not become a factor of a defect such as a leak path. Accordingly, in the first embodiment, the polishing processing by the CMP method does not need to be performed to the interlayer insulation film IL, so that the manufacturing costs can be reduced.

Then, as shown in FIG. 18, by forming the plug PG in the indent ILa, the contact area with the source electrode SE and the plug PG can be increased, and the wiring resistance from the source electrode SE to the drawer portion FPa can be reduced.

As described above, according to the first embodiment, the occurrence of the residue RS1 can be suppressed, so that the reliability of the semiconductor device 100 can be improved and, simultaneously, the manufacturing costs can be reduced.

As described above, the present invention has been specifically explained based on the above embodiments, but the present invention is not limited to the above embodiments and can be variously modified within a range not departing from the gist thereof.

What is claimed is:

1. A method of manufacturing a semiconductor device, the method comprising:
(a) preparing a semiconductor substrate of a first conductive type, the semiconductor substrate having an upper surface and a lower surface;
(b) after the (a), forming a trench in the semiconductor substrate so as to reach a predetermined depth toward the lower surface of the semiconductor substrate from the upper surface of the semiconductor substrate;
(c) after (b), forming a first insulation film on the upper surface of the semiconductor substrate and in the trench;
(d) after the (c), forming a first conductive film on the first insulation film so as to fill the trench;
(e) after the (d), removing the first conductive film located outside the trench, thereby forming the first conductive film left in the trench as a field plate electrode;
(f) after the (e), recessing the field plate electrode;
(g) after the (f), removing the first insulation film located on the upper surface of the semiconductor substrate and while recessing the first insulation film in the trench so that a position of an upper surface of the first insulation film becomes lower than a position of an upper surface of the field plate electrode;
(h) after the (g), forming a gate insulation film on the upper surface of the semiconductor substrate and in the trench located on the first insulation film while forming a second insulation film so as to cover the field plate electrode exposed from the first insulation film;
(i) after the (h), forming a second conductive film on the gate insulation film and on the second insulation film so as to fill the trench;
(j) after the (i), removing the second conductive film located outside the trench, thereby forming the second conductive film left in the trench on the field plate electrode as a gate electrode; and
(k) after the (j), selectively removing a portion of the gate electrode covering a drawer portion via the second insulation film, the drawer portion being a part of the field plate electrode,
wherein the drawer portion of the field plate electrode is provided for supplying a potential to the field plate electrode.

2. The method according to claim 1,
wherein the (f) is performed without using a resist pattern and is performed by an anisotropic etching processing under a condition that the field plate electrode is more easily etched than the first insulation film.

3. The method according to claim 1,
wherein in the (f), the upper surface of the field plate electrode including the drawer portion becomes lower than the upper surface of the semiconductor substrate.

4. The method according to claim 3,
wherein a position of an upper surface of the drawer portion is a same as a position of the upper surface of the field plate electrode other than the drawer portion.

5. The method according to claim 3, further comprising:
(l) after the (k), forming an interlayer insulation film on the upper surface of the semiconductor substrate so as to cover the trench;
(m) after the (l), forming a hole reaching the drawer portion in the interlayer insulation film;
(n) after the (m), forming a plug in the hole; and
(o) after the (n), forming a source electrode on the interlayer insulation film,
wherein in the (k), the interlayer insulation film is formed in the trench so as to cover the drawer portion via the second insulation film, and
wherein the drawer portion is electrically connected to the source electrode via the plug.

6. The method according to claim 5,
wherein after the (l), a polishing processing by a CMP method is not performed to the interlayer insulation film.

7. The method according to claim 5,
wherein an indent is formed in the interlayer insulation film so that an upper surface of the interlayer insulation film located over the drawer portion becomes lower than an upper surface of other portion of the interlayer insulation film,
wherein the hole communicates with the indent and is included in the indent in plan view, and
wherein the plug is formed in the hole and in the indent.

8. The method according to claim 7,
wherein a contact area with the source electrode and the plug is wider than a contact area with the drawer portion and the plug.

9. The method according to claim 1,
wherein in the (j), a polishing processing using a CMP method is performed by using the gate insulation film located outside the trench as an etching stopper, thereby removing the second conductive film located outside the trench.

10. The method according to claim 9,
wherein the gate insulation film and the second insulation film are silicon oxide films,
wherein the second conductive film is a polycrystalline silicon film, and
wherein in the polishing processing performed in the (j), solution containing NH₄OH and slurry containing colloidal silica are used.

11. The method according to claim 1,
wherein the (k) includes:
(k1) forming a resist pattern selectively covering a portion of the gate electrode, the portion covering the field plate electrode other than the drawer portion; and
(k2) performing an anisotropic etching processing by using the resist pattern as a mask, thereby selectively removing a portion of the gate electrode covering the drawer portion.

12. A semiconductor device comprising:
a semiconductor substrate of a first conductive type, the semiconductor substrate having an upper surface and a lower surface;
a trench formed in the semiconductor substrate so as to reach a predetermined depth toward the lower surface of the semiconductor substrate from the upper surface of the semiconductor substrate;
a field plate electrode formed in the trench and electrically insulated from the semiconductor substrate; and
a gate electrode formed over the field plate electrode and electrically insulated from the semiconductor substrate and the field plate electrode in the trench,
wherein a part of the field plate electrode configures a drawer portion for supplying a potential to the field plate electrode, and
wherein an upper surface of the field plate electrode including the drawer portion is lower than the upper surface of the semiconductor substrate.

13. The semiconductor device according to claim 12,
wherein a position of an upper surface of the drawer portion is a same as a position of the upper surface of the field plate electrode other than the drawer portion.

14. The semiconductor device according to claim 12, further comprising:
an interlayer insulation film formed on the upper surface of the semiconductor substrate so as to cover the trench;
a hole formed in the interlayer insulation film and reaching the drawer portion;
a plug formed in the hole; and
a source electrode formed on the interlayer insulation film,
wherein the interlayer insulation film is formed in the trench so as to cover the drawer portion, and
wherein the drawer portion is electrically connected to the source electrode via the plug.

15. The semiconductor device according to claim 14,
wherein an indent is formed in the interlayer insulation film so that an upper surface of the interlayer insulation film located over the drawer portion becomes lower than an upper surface of other portion of the interlayer insulation film,
wherein the hole communicates with the indent and is included in the indent in plan view, and
wherein the plug is formed in the hole and in the indent.

16. The semiconductor device according to claim 15,
wherein a contact area with the source electrode and the plug is wider than a contact area with the drawer portion and the plug.
